(19) United States
(12) Patent Application Publication
(10) Pub. No.: US 2023/0184061 A1
(43) Pub. Date: Jun. 15, 2023

(54) Machine Learning with Physics-based Models to Predict Multilateral Well Performance

(71) Applicant: Saudi Arabian Oil Company, Dhahran (SA)

(72) Inventors: Ayman Alkhalaf, Dhahran (SA); Said Almalki, Dhahran (SA); Obiomalotaoso Leonard Isichei, Dhahran (SA)

(21) Appl. No.: 17/549,015

(22) Filed: Dec. 13, 2021

(51) Int. Cl. E21B 41/00

(52) U.S. Cl. CPC E21B 41/0035; E21B 2200/20; E21B 2200/22

(57) ABSTRACT

A system and method for machine learning with physics-based models to predict multilateral well performance are provided. An exemplary method enables obtaining data associated with well completion, data associated with inflow control valves, and reservoir attributes of multilateral wells. Production scenarios are generated based on the data associated with well completion, the data associated with inflow control valves, and the reservoir attributes of the multilateral wells. The production scenarios are input into a physics-based model of the multilateral wells, and simulation data associated with the multilateral wells output from the physics-based model is obtained. A neural network based machine learning model is trained using the simulation data associated with the multilateral wells and target parameters associated with the multilateral wells, wherein the trained machine learning model is configured to predict multilateral well production parameters.

### TECHNICAL FIELD

This disclosure relates to a determination of multilateral well performance.

### BACKGROUND

In the recovery of hydrocarbons from subterranean formations having hydrocarbon-bearing reservoirs, wellbores are drilled with multiple highly deviated or horizontal portions that extend through separate hydrocarbon-bearing production zones. Such multilateral wells include branches or laterals from a motherbore that extend into the separate hydrocarbon-bearing production zones. Multilateral wells are used for hydrocarbon production from “tight” reservoirs.

### SUMMARY

An embodiment described herein provides a method for using machine learning with physics-based models to predict multilateral well performance. The method includes obtaining data associated with well completion, data associated with inflow control valves, and reservoir attributes of multilateral wells and generating production scenarios based on the data associated with well completion, the data associated with inflow control valves, and the reservoir attributes of the multilateral wells. The method also includes inputting the production scenarios into a physics-based model of the multilateral wells, wherein the physics-based model is built using one or more well tests and obtaining simulation data associated with the multilateral wells output from the physics-based model. A neural network based machine learning model is trained using the simulation data associated with the multilateral wells and target parameters associated with the multilateral wells, wherein the trained machine learning model is configured to predict multilateral well production parameters.

Another embodiment described herein provides a system for using machine learning with physics-based models to predict multilateral well performance. The system includes a processor that executes instructions that obtain data associated with well completion, data associated with inflow control valves, and reservoir attributes of multilateral wells and generate production scenarios based on the data associated with well completion, the data associated with inflow control valves, and the reservoir attributes of the multilateral wells. The instructions also input the production scenarios into a physics-based model of the multilateral wells, wherein the physics-based model is built using one or more well tests and obtain simulation data associated with the multilateral wells output from the physics-based model. A neural network based machine learning model is trained using the simulation data associated with the multilateral wells and target parameters associated with the multilateral wells, wherein the trained machine learning model is configured to predict multilateral well production parameters.

Another embodiment described herein provides an apparatus for using machine learning with physics-based models to predict multilateral well performance. The apparatus includes a processor that executes instructions that obtain data associated with well completion, data associated with inflow control valves, and reservoir attributes of multilateral wells and generate production scenarios based on the data associated with well completion, the data associated with inflow control valves, and the reservoir attributes of the multilateral wells. The instructions also input the production scenarios into a physics-based model of the multilateral wells, wherein the physics-based model is built using one or more well tests and obtain simulation data associated with the multilateral wells output from the physics-based model. A neural network based machine learning model is trained using the simulation data associated with the multilateral wells and target parameters associated with the multilateral wells, wherein the trained machine learning model is configured to predict multilateral well production parameters.

### BRIEF DESCRIPTION OF DRAWINGS

FIG. 1 is a schematic diagram of a well site for a multilateral completion and a multilateral completion evaluation system in accordance with an embodiment of the disclosure.

FIG. 2A is a block diagram of a hybrid model building pipeline.

FIG. 2B is an illustration of a graph of physics-based model data generation training time.

FIG. 3A is a block diagram of a process for hybrid model training.

FIG. 3B is a table that illustrates input parameters according to a well type and potential sources.

FIG. 3C is an illustration of an exemplary dashboard that has been utilized for deployment.

FIG. 3D is an illustration of gross rate prediction error.

FIG. 4 is a block diagram of a process for machine learning with physics-based models to predict multilateral well performance

FIG. 5 is a schematic illustration of an example controller that enables machine learning with physics-based models to predict multilateral well performance according to the present disclosure.

### DETAILED DESCRIPTION

Embodiments described herein enable using machine learning with physics-based models to predict multilateral well performance. In embodiments, physics-based models are developed to construct, calibrate and ultimately optimize an Inflow Control Valve (ICV) setting associated with multilateral smart completion wells through iteratively estimating productivity index (PI) for every lateral. Generally, physics-based models are defined by one or more governing physics model equations to incorporate process variations using independent process parameters. Machine learning techniques apply knowledge generated by the physics-based models to generate predicted production values, enabling a much faster optimization speed for large-scale implementation across multilateral wells. The present techniques also accurately predict a virtual rate contribution from each lateral or compartment for multilateral wells.

Data is generated from the physics-based models to simulate the multilateral wells one time (e.g., at a single instance), and a machine learning model is trained using the simulation data output by the physics-based models. In examples, the real time pressure data and valve settings associated with laterals or compartments are input to a trained machine learning model to predict virtual rate contribution from each lateral or compartment. Additionally, wellhead pressures and inflow control valve (ICV) settings are also predicted to achieve specific production flowrates from multilateral wells. Generally, the multilateral well modeling and performance prediction as described herein evaluates interplay between branches or laterals and pressure drop behaviors. In embodiments, the present techniques result in a reduction in storage requirements associated with physics-based models by 99%, and an improvement in computation speed by orders of magnitude of approximately ×6000.

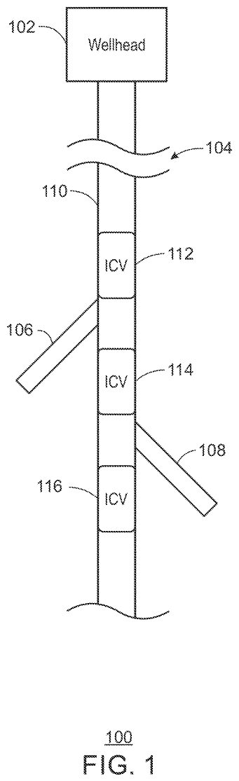

FIG. 1 is a schematic diagram of a well site 100 having a wellhead 102 for a multilateral completion 104 (that is, a completed multilateral well) having a first lateral 106, a second lateral 108, and a motherbore 110. FIG. 1 also depicts a first ICV 112, a second ICV 114, and a third ICV 116 disposed in the multilateral completion 104. In the example of FIG. 1, the wellhead 102 controls the production of hydrocarbons from the multilateral completion 104 via various functionalities and components known in the art. The ICV's 112, 114, and 116, control the flowrate of produced hydrocarbons from various segments of the multilateral completion 104. For example, the ICV 116 is used to control the flowrate of hydrocarbons from components below lateral 108. The ICV 114 is used to control the flowrate of hydrocarbons from the second lateral 108. Additionally, the ICV 112 is used to control the flowrate of hydrocarbons from the first lateral 106. In some embodiments, a hybrid model is used to evaluate the performance of the multilateral completion 104 using the techniques described herein. Additionally, the predictions made by the hybrid model provide for the adjustment of wellhead pressures in the wellhead 102 and the adjustment of the ICV's 112, 114, and 116.

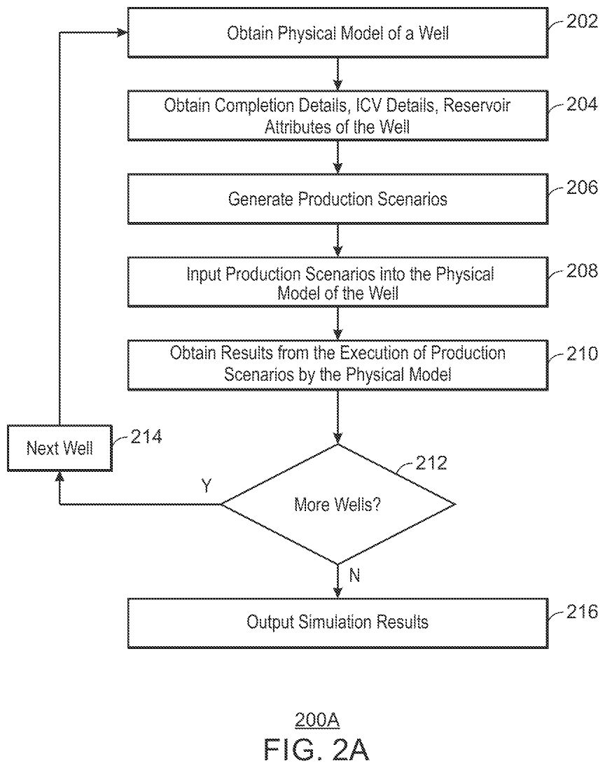

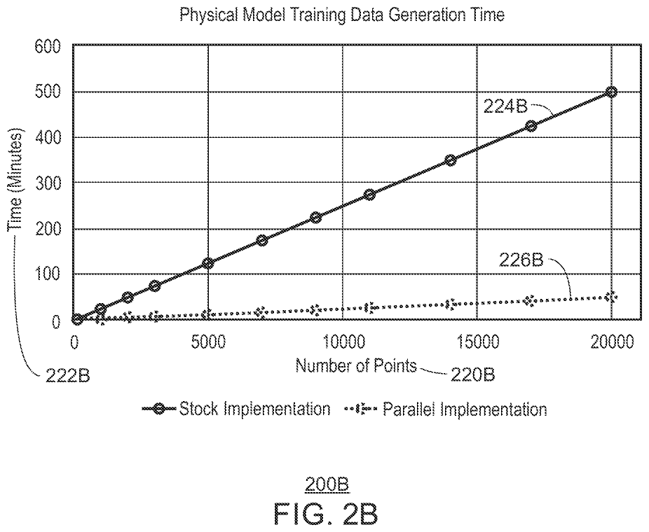

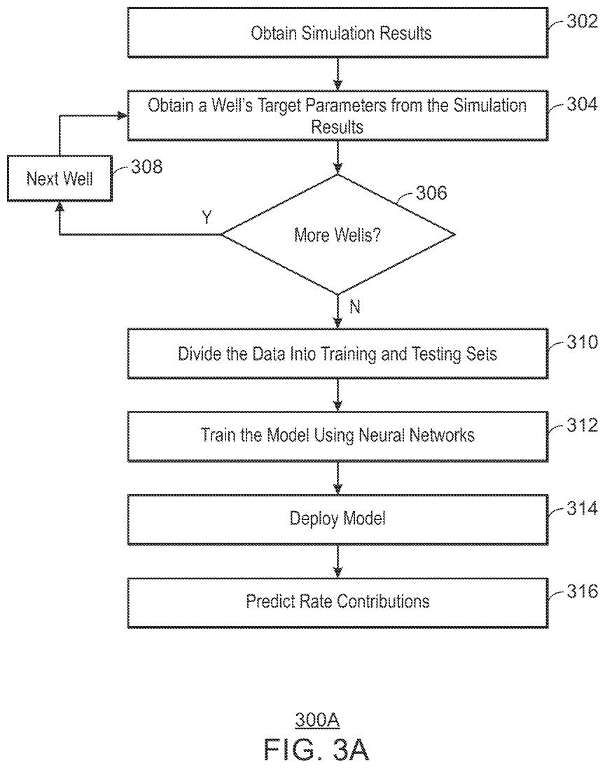

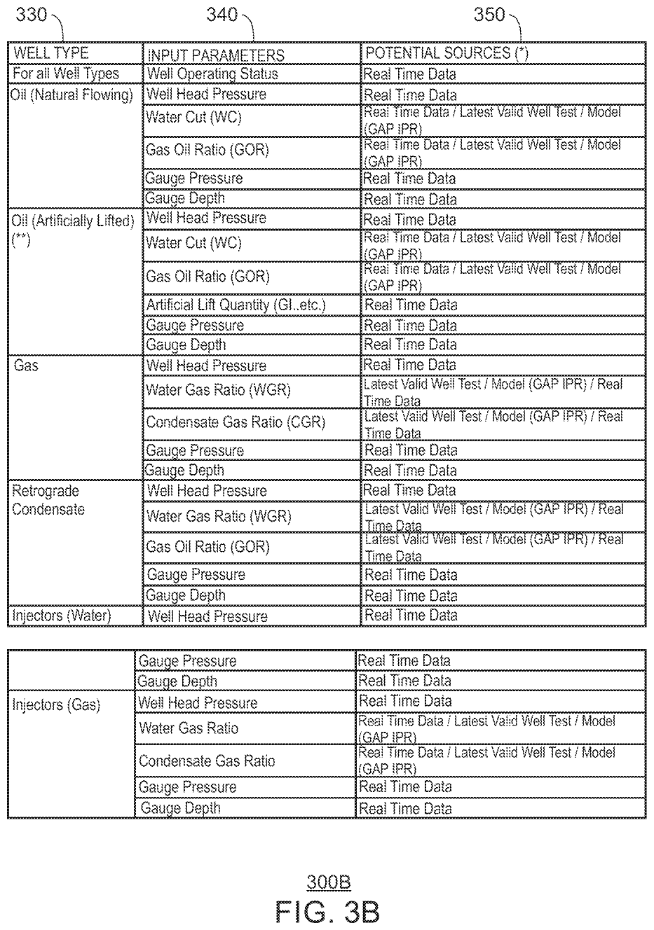

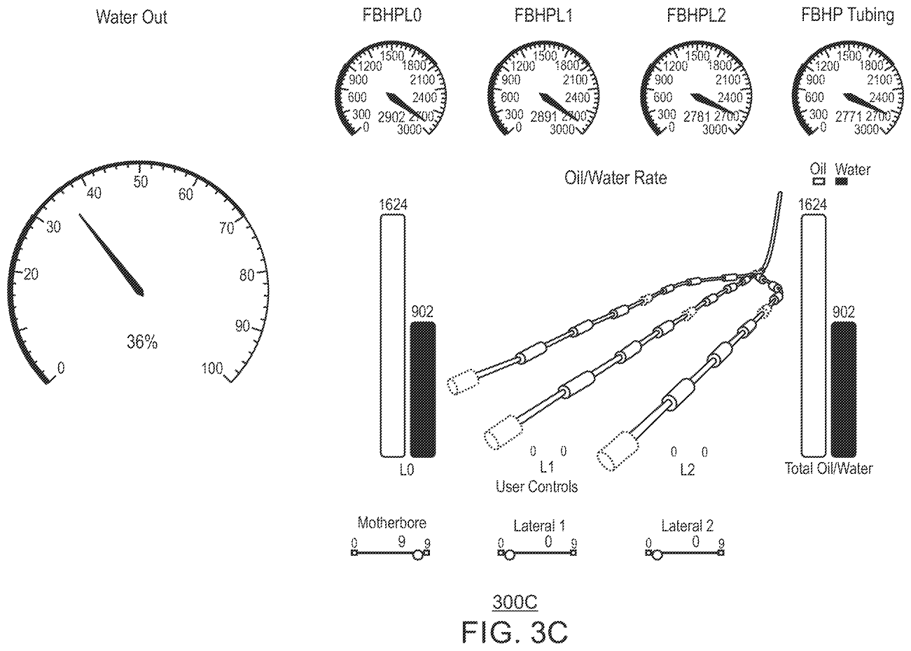

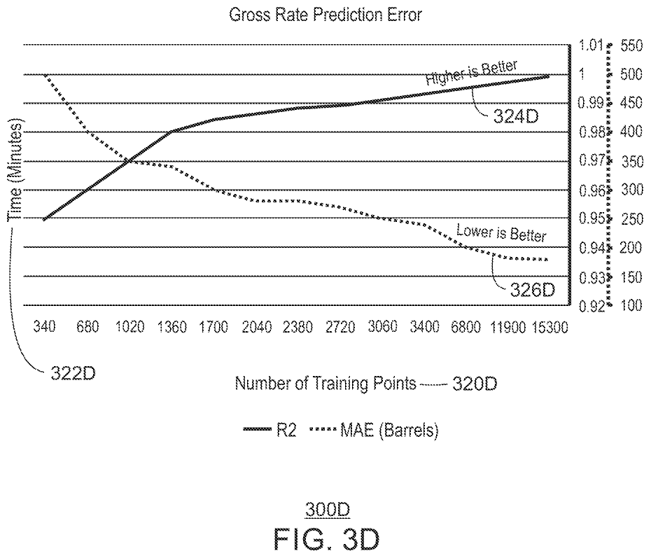

FIG. 2A is a block diagram of a hybrid model building pipeline 200A: In embodiments, the hybrid model building pipeline 200A generates training data using one or more physics-based models. As described with respect to FIG. 3A, the hybrid model is trained using data output by the hybrid model building pipeline 200A. Generally, the present techniques operate in two stages by initially generating simulation data from physics-based models and then training data-driven models using simulation data output by the physics-based model. Accordingly, in embodiments, the machine learning model trained using simulation data output by the physics-based model is a hybrid model. The hybrid model enables learning from the physics-based model on how the multilateral wells produce to predict future information of the same multilateral wells without direct theoretical knowledge of the multilateral wells. This hybrid modeling enables faster optimization of the performance of multilateral smart completion wells through the use of data-driven models while maintaining high-level accuracy of physics-based models. As used herein, a smart well completion is a process of making a well ready for production or injection after general drilling operations, where permanent downhole sensors and surface-controlled downhole flow control valves enable recordation, evaluation, and active management of production in real time without any well interventions.

At block 202, one or more physics-based models of a well are obtained. In embodiments, the one or more physics-based models is stored in a database. Generally, physics-based models are built using one or more well tests, such as tests to determine wellhead pressure, reservoir pressure, and vertical flow correlations. In embodiments, the physics-based models are built using physics-based petroleum engineering correlations. As used herein, the term “well test” refers to the measurement of a stabilized flowrate and a wellbore flowing pressure under a specific wellhead pressure. Well test conditions such as wellhead pressure, reservoir pressure, and vertical flow correlation may be used in the model and then used to determine a specific productivity index associated with a flowrate that matches the well test. In examples, the executable computer code predicts optimal ICV settings.

In examples, creating a physics-based model includes determining a productivity index for each lateral by iteratively altering the productivity index until the individual lateral flowrate based on a known reservoir pressure is matched. The productivity index is iteratively altered until a commingled flowrate is matched. The commingled flowrate matching is performed by reducing an intermediate productivity index for each lateral by the same percentage (that is, by the same fractional amount) and averaging the intermediate productivity index for each test. For example, a “match” may include a numerical comparison of the flowrates to determine whether the values are within a threshold amount, such as within at least 0.5%, at least 1%, at least 1.5%, at least 2%, at least 2.5%, at least 3%, at least 3.5%, at least 4%, or at least 5%. If the calculated flowrate does not match the well test flowrate, then the productivity index for each lateral is reduced by the same percentage and the current test is run again and the flowrate is calculated. In this manner, the productivity index for each lateral is reduced by the same percentage until a match between the calculated flowrate from the test and the well test flowrate is obtained.

The productivity index is used to set wellhead pressures and inline control valve (ICV) settings for production. In particular, based on the final productivity index for each lateral, wellhead pressures (WHP), inline control valves (ICVs), or both are adjusted to achieve a desired productivity from the multilateral completion. The physics-based models calculate production values a single time, including the individual and multi-rate commingled test of the laterals and accounts for the interplay between laterals of the multilateral completion.

At block 204, metadata associated with each respective well is obtained. As used herein, metadata refers to information regarding various aspects of the data associated with the physics-based models. For example, metadata includes a well's completion details, ICV details, reservoir attributes and the like. Well completion details refer to the attributes of the shape, geometry, and casing of the well. This includes, for example, a deviation survey, number of casings, type of casing, depth of the casing, the placement of packers, the diameter of tubing, ESP placement and specs (if so equipped), and gas lift configuration (if so equipped). ICV details refer to number of laterals, geometry of laterals, placement of laterals, type of valves (i.e. manufacturers' specs). In embodiments, this metadata dictates the type of production scenarios that can be generated. Generally, reservoir attributes refer to porosity, permeability, hydrocarbon accumulation associated with a reservoir, water cut, gas/oil ratio (GOR), reservoir pressure and productivity index. The reservoir includes one or more multilateral wells.

At block 206, production scenarios are generated. A production scenario is a set of inputs that are used by the physics-based model to simulate the multilateral well in different situations. This process generates 10,000 unique production scenarios to be input into the physics-based model. For example, a production scenario includes determining optimal ICV settings given reservoir conditions and well settings (e.g., gas-to-oil ratio, water-cut, productivity index, artificial lift quantity, and the like).

At block 208, the production scenarios are input into the physics-based model. To input the production scenarios into the physics-based model, a set of inputs is determined that can be used by the physics-based model to generate predictions. In embodiments, to find the optimal set of inputs, a historical database that includes historic well data is accessed and the historical readings of the well are obtained. The range of the obtained historical values is used to construct an optimal set of inputs that covers most production scenarios the well has experienced over the years. Generally, historical readings include multiple tests conducted to understand the performance of each lateral and the commingled performance of the well. The test parameters include well head pressure, choke downstream pressure, electric submersible pump (ESP) frequency, liquid rate, water cut, GOR, downhole pressures (e.g., intake pressure, discharge pressure, pressure downhole monitoring system (PDHMS), annulus pressure, tubing pressure), reservoir pressure, downhole temperatures (e.g., temperatures at the ICV), individual lateral productivity index, and any combinations thereof.

At block 210, results from the execution of production scenarios by the physics-based model of a well are obtained. At block 212, it is determined if there are more wells available. If more wells are available, at block 214 the next well is selected, and process flow returns to block 202 where a physics-based model of the next well is obtained. If no more wells are available, process flow continues to block 216. At block 216, simulation results for each well are output.

In embodiments, multiple wells are processed in parallel to obtain results from the execution of production scenarios by the physical model. For example, multiple processes utilize different cores in the same CPU perform the calculations. The parallel implementation has achieved ×10 improvement in the time needed to finish simulations processing time per well. FIG. 2B is an illustration of a graph 200B of physics-based model data generation training time. In the example of FIG. 2B, a number of data points is illustrated along the x-axis 220B. Time is illustrated along the y-axis 222B. Using traditional processes for well-completion model evaluation, processing time increases proportionally with the number of data points evaluated as illustrated by line 224B. For the parallel implementation described herein, the increase in number of points evaluated result in minimal increases in processing time, as illustrated by line 226B.

FIG. 3A is a block diagram of a process 300A for hybrid model training. As described with respect to FIG. 2A, the hybrid model building pipeline generates training data using one or more physics-based models. In embodiments, the process 300A of FIG. 3A trains a hybrid model using simulation data output by the hybrid model building pipeline 200A. Accordingly, at block 302, the simulation results are obtained. The process 200A is done for every well iteratively until all wells are complete.

At block 304, a well's target parameters from the simulation data are obtained. Generally, the target parameters include input and output parameters associated with the multilateral well. In examples, input parameters are defined, at least in part, based on a predetermined well type. Generally, input parameters include reservoir attributes and well settings that are defined based on the well type. FIG. 3B is a table 300B that illustrates input parameters 340 according to a well type 330 and potential sources 350. In the table 300B, a first column 330 provides a well type. Exemplary well types include, for example, natural flowing oil, artificially lifted oil, gas, retrograde condensate, water injectors and gas injectors. In the table 300B, information for all well types is also provided. Accordingly, while particular well types are described, the present techniques are applicable to all well types. Generally, output parameters include individual lateral contribution (e.g., rate) of oil water and gas in addition to the predicted overall gas/oil ratio, water cut, and predicted flowing bottomhole pressure.

For each well type 330, corresponding input parameters are illustrated in column 340. Each input parameter corresponds to one or more potential sources at illustrated in column 350. Generally, input parameters include well operating status, well head pressure, water cut, gas oil ratio, gauge pressure, gauge depth, water gas ratio, condensate gas ratio, and the like. Generally, potential sources of the input variables include real time data, latest valid well test data, and gap inflow performance relationship (IPR) data, and the like.

Referring again to FIG. 3A, at block 306, it is determined if there are more wells available for processing. If there are more wells available for processing, the next well is selected at block 308, and process flow returns to block 304. If there are no more wells, process flow continues to block 310. At block 310, the simulation data is divided into training and testing sets: The division of simulation data is done through non-exhaustive cross validation, such as a k-fold cross validation scheme. In embodiments, the present techniques implement a 5-fold cross validation scheme, where k=5. Generally, cross-validation is a statistical method used to evaluate performance of machine learning models. Additionally, k-fold cross validation schemes also fine tunes hyperparameters of the machine learning model.

For example, in k-fold cross-validation, the original sample is randomly partitioned into k equal sized subsamples. In embodiments, k can be any number, such as k=3, k=5, or k=10. Generally, of the k subsamples, a single subsample is retained as the validation data for testing the model, and the remaining k−1 subsamples are used as training data. In embodiments, 80% of the simulation data is used for training and 20% for testing. The cross-validation process is then repeated k times, with each of the k subsamples used exactly once as the validation data. The k results can then be averaged to produce a single estimation. In this manner, all simulation data are used for both training and validation, and each simulation data is used for validation exactly once. This ensures that the performance of the machine learning model is reproducible.

At block 312, the neural network based machine learning model is trained. In embodiments, a randomized search algorithm is implemented to find a best set of hyperparameters that represents the simulation data. In a randomized search, a grid of hyperparameter values is generated and random combinations are selected to train the model. The random combinations are scored. The number of search iterations is set based on time/resources. Generally, initial machine learning model hyperparameters are set by a data scientist ahead of training and control implementation aspects of the model. The hyperparameters are distinct from the model parameters (e.g., input and output parameters), which are learned during training. In examples, hyperparameter tuning enables determining the combination of hyperparameter values for a machine learning model that performs the best (as measured on a validation dataset) for a problem. In embodiments, the randomized search algorithm fine tunes one or more hyperparameters, such as neural network size, number of nodes in each layer, learning rate, activation function, solver, and max number of iterations. In embodiments, the best hyperparameters are the ones that minimize the error between actual output values resulting from input values and predicted values output by the machine learning model from the same input values.

At block 314, the trained model is deployed. The trained model is evaluated using two metrics: R-squared and mean absolute error (MAE). Generally, R-squared represents the coefficient of how well the values fit compared to the original values. In embodiments, the value is from 0 to 1, interpreted as percentages. The higher the value is, the better the model is. MAE represents the difference between the original and predicted values extracted by averaged the absolute difference over the data set. FIG. 3D is an illustration of gross rate prediction error. In the example of FIG. 300D, a number of training points is illustrated along the y-axis 320D. Time in minutes is illustrated along the y-axis 322D. For R-squared illustrated at line 324D, higher is better. For the mean absolute error (in barrels) illustrated at line 326D, lower is better. Generally, the amount of data the model trains with affects the accuracy of the hybrid model. FIG. 3D demonstrates this correlation. More data for training yields better performing models. In embodiments, the hybrid models according to the present techniques have an R-squared of ˜0.99 and mean absolute error of ˜3%.

Referring again to FIG. 3A, at block 316, the trained model predicts, in real-time, a virtual rate contribution from each lateral or compartment for smart completion wells. Upon a successful evaluation of the model using R-squared, MAE, or any combinations thereof, the model is deployed on a server and is interfaced with using a web service. In examples, a web service is offered by an electronic device to another electronic device, communicating with each other via the World Wide Web, or a server running on a computer device, listening for requests at a particular port over a network, serving web documents. The predictions are rendered at a display via the web service, in real time.

FIG. 3C is an illustration of an exemplary dashboard 300C that has been utilized for deployment. The dashboard 300C includes a rendering, in real-time, of predictions associated with multilateral wells at a display via a web service. As illustrated on the dashboard 300C, various flowing bottomhole pressures are illustrated. Additionally water cut is also illustrated. User controls are provided for each lateral and motherbore. In examples, the laterals and motherbore correspond to the laterals and motherbore illustrated in FIG. 1. Accordingly, FIG. 3C is an illustration of a dashboard 300C with visualization results. In embodiments, coordinated building of a visualization dashboard seamlessly linked to the hybrid model to enables engineers to execute future production scenarios faster and visualize the results of the optimization on the dashboard 300C. In embodiments, the hybrid model is connected with real time pressure and valve setting sensor data installed across each lateral and accurately predicts in real-time virtual rate contributions from each lateral or compartment for smart completion wells. The data-driven, hybrid model according to the present techniques is significantly smaller than traditional physics-based models, and orders of magnitude faster in processing simulation scenarios

The use of a neural network based machine learning model is distinguished from the use of tree-based machine learning models. In examples, the neural network based machine learning model fits parameters to transform the input and indirectly directs the activations of following neurons according to probabilistic evaluations of the training data. The visualization dashboard is linked to the hybrid model to enable engineers to run different scenarios faster and visualize the results of the optimization on the dashboard. In operation, the hybrid model is communicatively coupled with real time pressure and valve setting sensor data installed across each lateral and was proven effective to accurately predict in real-time virtual rate contribution from each lateral or compartment for smart completion wells.

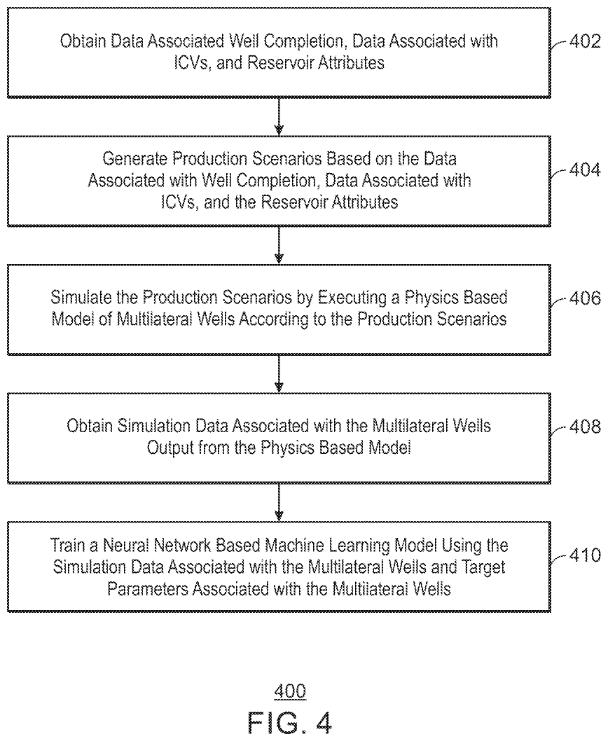

FIG. 4 is a block diagram of a process 400 for machine learning with physics-based models to predict multilateral well performance. At block 402, metadata associated with well completion, data associated with ICV details, and reservoir attributes of multilateral wells are obtained. In examples, the metadata is associated with data generated by a physics-based model of multilateral wells in a reservoir.

At block 404, production scenarios are generated based on the completion details, the ICV details, and the reservoir attributes of the multilateral wells. In embodiments, the metadata dictates the type of production scenarios that can be generated. At block 406, the production scenarios are input into a physics-based model. In examples, the physics-based model is built using data captured from well tests such as wellhead pressure, reservoir pressure, and vertical flow correlations. Generally, a well test consists of changing the production rate and observing the change in pressure caused by this change in production rate. When performing a well test, the time, the rate, the pressure, are measured, and the rate is controlled.

At block 408, simulation data output from the physics-based model based on the multilateral wells is obtained. In embodiments, production of the multilateral wells is simulated to generate simulation data from the physics-based dataset. In embodiments, the physics-based model is a mathematical description of the multilateral wells. In embodiments, the physics-based model provides a description of the multilateral wells based on physical data. However, solving the physics-based model is time-consuming and consumes a large amount of compute processing resources. Thus, a pure physics-based approach is unable to output real-time predictions on in response to live, real-time data. In embodiments, the present techniques determine the output of the physics-based models (e.g., simulation data) a single time.

At block 410, a neural network based machine learning model is trained using the simulation data associated with the multilateral wells, wherein the trained machine learning model is configured to predict multilateral well production parameters. In embodiments, to train the machine learning model, the simulation data is divided into a training dataset and a test dataset. In embodiments, a data-driven, hybrid model is generated by training a neural networks to predict production values of the multilateral wells according to production scenarios. In particular, the hybrid model according to the present techniques predicts one or more inflow control valve (ICV) settings of a multilateral well. In embodiments, the hybrid model is validated using k-fold cross-validation based on the simulation data. Evaluation of the hybrid model includes calculating metrics such as R-squared and MAE.

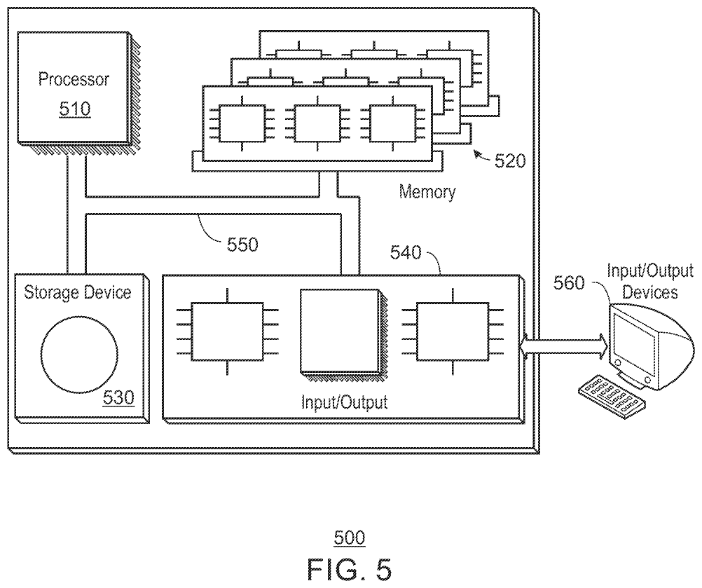

FIG. 5 is a schematic illustration of an example controller 500 (or control system) that enables machine learning with physics-based models to predict multilateral well performance according to the present disclosure. For example, the controller 500 may include or be part of the control system that controls components associated with a well, such as the well site 100 having a wellhead 102 for a multilateral completion 104 shown in FIG. 1. The controller 500 can generate physics-based models of a multilateral well, and use data output by the multilateral well to train a neural network based machine learning model. The controller 500 is intended to include various forms of digital computers, such as printed circuit boards (PCB), processors, digital circuitry, or otherwise parts of a system determining an optimal perforation orientation for hydraulic fracturing slant wells. Additionally the system can include portable storage media, such as, Universal Serial Bus (USB) flash drives. For example, the USB flash drives may store operating systems and other applications. The USB flash drives can include input/output components, such as a wireless transmitter or USB connector that may be inserted into a USB port of another computing device.

The controller 500 includes a processor 510, a memory 520, a storage device 530, and an input/output device interface 540 (for displays, input devices, example, sensors, valves, pumps). Each of the components 510, 520, 530, and 540 are interconnected using a system bus 550. The processor 510 is capable of processing instructions for execution within the controller 500. The processor may be designed using any of a number of architectures. For example, the processor 510 may be a CISC (Complex Instruction Set Computers) processor, a RISC (Reduced Instruction Set Computer) processor, or a MISC (Minimal Instruction Set Computer) processor.

In one implementation, the processor 510 is a single-threaded processor. In another implementation, the processor 510 is a multi-threaded processor. The processor 510 is capable of processing instructions stored in the memory 520 or on the storage device 530 to display graphical information for a user interface on the input/output device 540.

The memory 520 stores information within the controller 500. In one implementation, the memory 520 is a computer-readable medium. In one implementation, the memory 520 is a volatile memory unit. In another implementation, the memory 520 is a nonvolatile memory unit.

The storage device 530 is capable of providing mass storage for the controller 500. In one implementation, the storage device 530 is a computer-readable medium. In various different implementations, the storage device 530 may be a floppy disk device, a hard disk device, an optical disk device, or a tape device. In embodiments, the memory 520, storage device 530, or any combinations thereof stores a physics-based model of the multilateral wells as described herein.

The input/output interface 540 provides input/output operations for the controller 500. In one implementation, the input/output interface 540 is communicatively coupled with input/output devices 560 including a keyboard and/or pointing device. In another implementation, the input/output devices 550 include a display unit for displaying graphical user interfaces. In embodiments, the display renders a dashboard, in real-time, of predictions associated with multilateral wells. The dashboard may be, for example, the dashboard 300C of FIG. 3C. In embodiments, the controller 500 is communicatively coupled with smart well devices at the well site that enable real time predictions of production values for multilateral wells.

The features described can be implemented in digital electronic circuitry, or in computer hardware, firmware, software, or in combinations of them. The apparatus can be implemented in a computer program product tangibly embodied in an information carrier, for example, in a machine-readable storage device for execution by a programmable processor; and method steps can be performed by a programmable processor executing a program of instructions to perform functions of the described implementations by operating on input data and generating output. The described features can be implemented advantageously in one or more computer programs that are executable on a programmable system including at least one programmable processor coupled to receive data and instructions from, and to transmit data and instructions to, a data storage system, at least one input device, and at least one output device. A computer program is a set of instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

Suitable processors for the execution of a program of instructions include, by way of example, both general and special purpose microprocessors, and the sole processor or one of multiple processors of any kind of computer. Generally, a processor will receive instructions and data from a read-only memory or a random access memory or both. The essential elements of a computer are a processor for executing instructions and one or more memories for storing instructions and data. Generally, a computer will also include, or be operatively coupled to communicate with, one or more mass storage devices for storing data files; such devices include magnetic disks, such as internal hard disks and removable disks; magneto-optical disks; and optical disks. Storage devices suitable for tangibly embodying computer program instructions and data include all forms of non-volatile memory, including by way of example semiconductor memory devices, such as EPROM, EEPROM, and flash memory devices; magnetic disks such as internal hard disks and removable disks; magneto-optical disks; and CD-ROM and DVD-ROM disks. The processor and the memory can be supplemented by, or incorporated in, ASICs (application specific integrated circuits).

To provide for interaction with a user, the features can be implemented on a computer having a display device such as a CRT (cathode ray tube) or LCD (liquid crystal display) monitor for displaying information to the user and a keyboard and a pointing device such as a mouse or a trackball by which the user can provide input to the computer. Additionally, such activities can be implemented via touchscreen flat-panel displays and other appropriate mechanisms.

The features can be implemented in a control system that includes a back-end component, such as a data server, or that includes a middleware component, such as an application server or an Internet server, or that includes a front-end component, such as a client computer having a graphical user interface or an Internet browser, or any combination of them. The components of the system can be connected by any form or medium of digital data communication such as a communication network. Examples of communication networks include a local area network (“LAN”), a wide area network (“WAN”), peer-to-peer networks (having ad-hoc or static members), grid computing infrastructures, and the Internet.

While this specification contains many specific implementation details, these should not be construed as limitations on the scope of any inventions or of what may be claimed, but rather as descriptions of features specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products.

A number of implementations have been described. Nevertheless, it will be understood that various modifications may be made without departing from the spirit and scope of the disclosure. For example, example operations, methods, or processes described herein may include more steps or fewer steps than those described. Further, the steps in such example operations, methods, or processes may be performed in different successions than that described or illustrated in the figures. Accordingly, other implementations are within the scope of the following claims. Other implementations are also within the scope of the following claims.

What is claimed is:

1. A computer-implemented method, comprising:
obtaining, with at least one processor, data associated with well completion, data associated with inflow control valves, and reservoir attributes of multilateral wells;
generating, with the at least one processor, production scenarios based on the data associated with well completion, the data associated with inflow control valves, and the reservoir attributes of the multilateral wells;
inputting, with the at least one processor, the production scenarios into a physics-based model of the multilateral wells, wherein the physics-based model is built using one or more well tests;
obtaining, with the at least one processor, simulation data associated with the multilateral wells output from the physics-based model; and
training, with the at least one processor, a neural network based machine learning model using the simulation data associated with the multilateral wells and target parameters associated with the multilateral wells, wherein the trained machine learning model is configured to predict multilateral well production parameters.

2. The computer-implemented method of claim 1, wherein multilateral well production parameters comprise inflow control valve settings corresponding to laterals of the multilateral wells.

3. The computer-implemented method of claim 1, comprising:
dividing the simulation data into training and validation datasets; and
training the neural network based machine learning model using a randomized search algorithm applied to the simulation data associated with the multilateral wells output from the physics-based model.

4. The computer-implemented method of claim 1, comprising validating the trained machine learning model by evaluating R-squared values and mean absolute error (MAE) values.

5. The computer-implemented method of claim 1, wherein the target parameters are defined by a predetermined well type.

6. The computer-implemented method of claim 1, wherein the physics-based model is built by determining a productivity index for each lateral by iteratively altering the productivity index until the individual lateral flowrate based on a known reservoir pressure is matched.

7. The computer-implemented method of claim 1, wherein the production scenarios are generated as permutations of the data associated with well completion, the data associated with inflow control valves, and the reservoir attributes of the multilateral wells.

8. A system, comprising:
at least one processor, and
at least one non-transitory storage media storing instructions that, when executed by the at least one processor, cause the at least one processor to:
obtain data associated with well completion, data associated with inflow control valves, and reservoir attributes of multilateral wells;
generate production scenarios based on the data associated with well completion, the data associated with inflow control valves, and the reservoir attributes of the multilateral wells;
input the production scenarios into a physics-based model of the multilateral wells, wherein the physics-based model is built using one or more well tests;
obtain simulation data associated with the multilateral wells output from the physics-based model; and
train a neural network based machine learning model using the simulation data associated with the multilateral wells and target parameters associated with the multilateral wells, wherein the trained machine learning model is configured to predict multilateral well production parameters.

9. The system of claim 8, wherein multilateral well production parameters comprise inflow control valve settings corresponding to laterals of the multilateral wells.

10. The system of claim 8, comprising:
dividing the simulation data into training and validation datasets; and
training the neural network based machine learning model using a randomized search algorithm applied to the simulation data associated with the multilateral wells output from the physics-based model.

11. The system of claim 8, comprising validating the trained machine learning model by evaluating R-squared values and mean absolute error (MAE) values.

12. The system of claim 8, wherein the target parameters are defined by a predetermined well type.

13. The system of claim 8, wherein the physics-based model is built by determining a productivity index for each lateral by iteratively altering the productivity index until the individual lateral flowrate based on a known reservoir pressure is matched.

14. The system of claim 8, wherein the production scenarios are generated as permutations of the data associated with well completion, the data associated with inflow control valves, and the reservoir attributes of the multilateral wells.

15. An apparatus comprising a non-transitory, computer readable, storage medium that stores instructions that, when executed by at least one processor, cause the at least one processor to perform operations comprising:
obtain data associated with well completion, data associated with inflow control valves, and reservoir attributes of multilateral wells;
generate production scenarios based on the data associated with well completion, the data associated with inflow control valves, and the reservoir attributes of the multilateral wells;
input the production scenarios into a physics-based model of the multilateral wells, wherein the physics-based model is built using one or more well tests;
obtain simulation data associated with the multilateral wells output from the physics-based model; and
train a neural network based machine learning model using the simulation data associated with the multilateral wells and target parameters associated with the multilateral wells, wherein the trained machine learning model is configured to predict multilateral well production parameters.

16. The apparatus of claim 15, wherein multilateral well production parameters comprise inflow control valve settings corresponding to laterals of the multilateral wells.

17. The apparatus of claim 15, comprising:
dividing the simulation data into training and validation datasets; and
training the neural network based machine learning model using a randomized search algorithm applied to the simulation data associated with the multilateral wells output from the physics-based model.

18. The apparatus of claim 15, comprising validating the trained machine learning model by evaluating R-squared values and mean absolute error (MAE) values.

19. The apparatus of claim 15, wherein the target parameters are defined by a predetermined well type.

20. The apparatus of claim 15, wherein the physics-based model is built by determining a productivity index for each lateral by iteratively altering the productivity index until the individual lateral flowrate based on a known reservoir pressure is matched.
